(19) United States
(12) Patent Application Publication
(10) Pub. No.: US 2018/0356926 A1
(43) Pub. Date: Dec. 13, 2018

(54) TOUCH SCREEN DEVICE

(71) Applicant: MODA-INNOCHIPS CO., LTD., Ansan-Si, Gyeonggi-Do (KR)

(72) Inventors: Sung Chol PARK, Ansan-Si, Gyeonggi-Do (KR); Young Sul KIM, Seoul (KR); Yu Hyeong LEE, Hwaseong-Si, Gyeonggi-Do (KR); Wan PARK, Ansan-Si, Gyeonggi-Do (KR)

(21) Appl. No.: 15/781,107

(22) PCT Filed: Nov. 30, 2016
(86) PCT No.: PCT/KR2016/013972

§ 371 Date: Jun. 1, 2018

(30) Foreign Application Priority Data
Dec. 4, 2015 (KR) 10-2015-0172443

(51) Int. Cl. G06F 3/041; G06F 3/01

(52) U.S. Cl. CPC G06F 3/0412; H01L 41/09; G06F 3/016

(57) ABSTRACT

Disclosed is a touch screen apparatus including a frame, a touch screen panel provided inside the frame, and a piezoelectric vibration member provided between the frame and the touch screen panel, wherein the piezoelectric vibration member vibrates in a horizontal direction of the touch screen.

### BACKGROUND

The present disclosure relates to a touch screen apparatus, and more particularly, to a touch screen apparatus in which a haptic feedback is possible.

Liquid crystal displays (LCD) have been commonly used for various information transmission and AV systems. In addition, touch screens have been applied to LCDs for convenient interface with a driver. Touch screens are designed such that when a screen is touched by using a finger or a touch pen, an instruction is executed after the portion at which the touch has occurred or the position of a cursor is moved is detected.

Furthermore, a vibration generating device is applied to a touch screen and thereby, enables a user to instantaneously sense a feedback vibration with respect to a touch input of a user. That is, the vibration generating apparatus provided in a touch screen apparatus may be used as a means for a haptic feedback responding to a touch of a user with a vibration. The haptic feedback refers to a haptic sense which may be sensed through a finger tip (finger tip or stylus pen) of a user when the user touches an object. A haptic feedback means, which can recover a dynamic characteristic (vibration and haptic sense which are transferred to a finger when pushing a button by the finger, operation sound, or the like) with a responsibility similar to that in case of touching a real object (real button) when a person touches a virtual object (for example, button mark in a touch screen), can be said most ideal Accordingly, the vibration generating apparatuses are required to provide a vibration force sufficient for a person to sense vibration through a haptic sense.

Vibration motors, linear motors, or the like may be used as a vibration generating apparatus applied to the touch screen apparatuses. Accordingly, in a touch screen apparatus for a haptic feedback, a transparent touch screen panel is disposed to be brought into close contact with an image display apparatus for displaying an image, such as an LCD, and when a user presses the touch screen panel while viewing an image displayed on the image display apparatus through the touch screen panel, it is configured that a vibration may be generated in the touch screen panel by a vibration motor or a linear motor and transferred to the user. Here, the vibration generating apparatus is mounted on a board provided inside the touch screen panel and covered by the touch screen panel. Accordingly, since the vibration force due to the vibration generating apparatus is transferred in the up-down direction with respect to the touch screen panel, there is a problem in that the vibration force transferred to the finger of the user is weak. In addition, since the vibration of the touch screen panel is generated in the up-down direction, a dead zone with a weak vibration force is generated on the touch screen panel and there is a problem of generating a vibration deviation for each position on the touch screen panel. That is, the farther a position from the vibration generating apparatus, the weaker the vibration force at the position, and a deviation of vibration is generated at each position.

Meanwhile, a piezoelectric vibration apparatus may be used as a vibration generating apparatus. In the piezoelectric vibration apparatus, a vibration plate is coupled to a coupling groove in an upper surface of a board, and the vibration plate is directly attached to a touch screen panel to thereby vibrate in the up-down direction of the touch screen panel. However, such method in related arts has a problem in that the vibration force is not uniform over the entire touch screen panel. Furthermore, since a mounting space for the piezoelectric vibration apparatus is reduced by the trend that the area of a touch screen panel is reduced while the number of modules integrated in a board is increased, the size and number of the piezoelectric vibration apparatus is reduced, and accordingly, the vibration may be weak. In addition, since the piezoelectric vibration apparatus is directly attached to a touch screen panel and vertically vibrates, unpleasant haptic sense may be increased.

[Prior Art Documents]

(Patent document 1) Korean Patent Application Laid-open No. 2014-0133658

### SUMMARY

The present disclosure provides a touch screen apparatus capable of increasing vibration force transferred to a user and provided with a piezoelectric vibration apparatus capable of providing uniform vibration force over the entire touch screen panel.

The present disclosure also provides a touch screen apparatus capable of increasing vibration force by providing the vibration force in the horizontal direction of a touch screen panel and provided with a piezoelectric vibration apparatus capable of providing uniform vibration force.

In accordance with an exemplary embodiment, a touch screen apparatus includes: a frame; a touch screen panel provided inside the frame; and a piezoelectric vibration member provided between the frame and the touch screen panel, wherein the piezoelectric vibration member vibrates in a horizontal direction of the touch screen.

The frame may have a shape which has at least an opened upper portion and closed side surfaces, wherein a stepped end portion may be formed on an inner side surface the frame.

The frame may further include a groove formed to accommodate the piezoelectric vibration member in an inner side surface thereof above the stepped end portion.

The touch screen panel may be provided to have edges thicker than other regions thereof, wherein the edges may be spaced a predetermined distance from the stepped end portion.

The touch screen apparatus may further include an adhesive provided in at least some regions between the stepped end portion and a lower side of the edges of the touch screen panel.

The touch screen apparatus may further include an extension part upwardly extending from the outer side of the stepped end portion, wherein the piezoelectric vibration member may be provided on a side surface of the extension part.

The touch screen apparatus may further include a cushion member including a spring provided between the frame and the touch screen panel.

The piezoelectric vibration member may include: a vibration plate having at least one region in which a hole is formed; a piezoelectric element, and a damper, wherein the vibration plate may be fixed to the frame, and the damper may be brought into contact with the touch screen panel.

The touch screen apparatus may further include a waterproof layer formed on at least a portion of the piezoelectric vibration member.

The vibration plate may be fixed to the frame by at least one of a screw, an adhesive, or coupling pin.

The touch screen apparatus may further include a case accommodating the piezoelectric vibration member.

The touch screen apparatus may further include an FPCB provided on one surface of the case.

The touch screen apparatus may further include a weight member brought into contact with the piezoelectric vibration member inside the case.

### BRIEF DESCRIPTION OF THE DRAWINGS

Exemplary embodiments can be understood in more detail from the following description taken in conjunction with the accompanying drawings, in which:

FIG. 1 is an exploded perspective view of a touch screen apparatus in accordance with an exemplary embodiment;

FIG. 2 is a perspective view of an assembled touch screen apparatus in accordance with an exemplary embodiment;

FIGS. 3 is a cross-sectional view taken along lines A-A′ and B-B′ of FIG. 2;

FIG. 4 is a schematic view of a piezoelectric vibration member applied to a touch screen apparatus in accordance with an embodiment of the present invention;

FIGS. 5 to 7 are cross-sectional views of touch screen apparatuses in accordance with other exemplary embodiments; and

FIGS. 8 and 9 are an exploded perspective view and a plan view of a piezoelectric vibration module applied to a touch screen apparatus in accordance with another exemplary embodiment.

### DETAILED DESCRIPTION OF EMBODIMENTS

Hereinafter, embodiments will be described in more detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art.

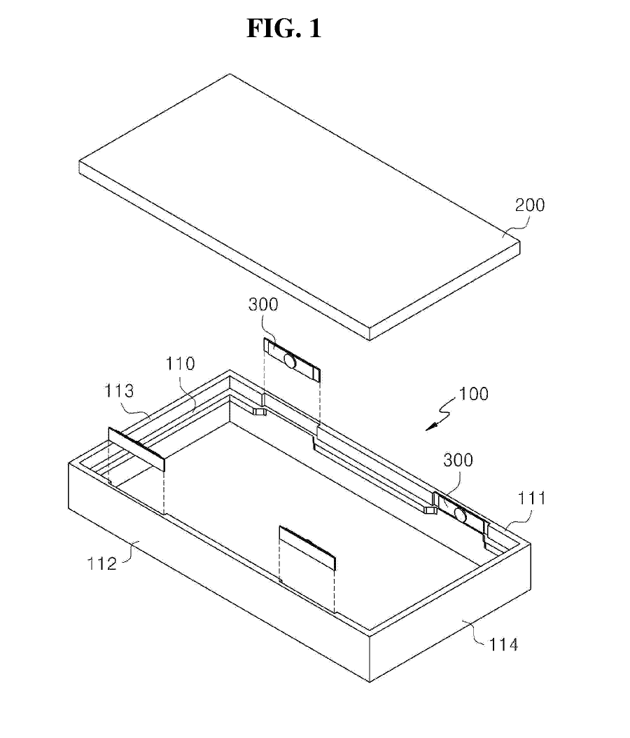

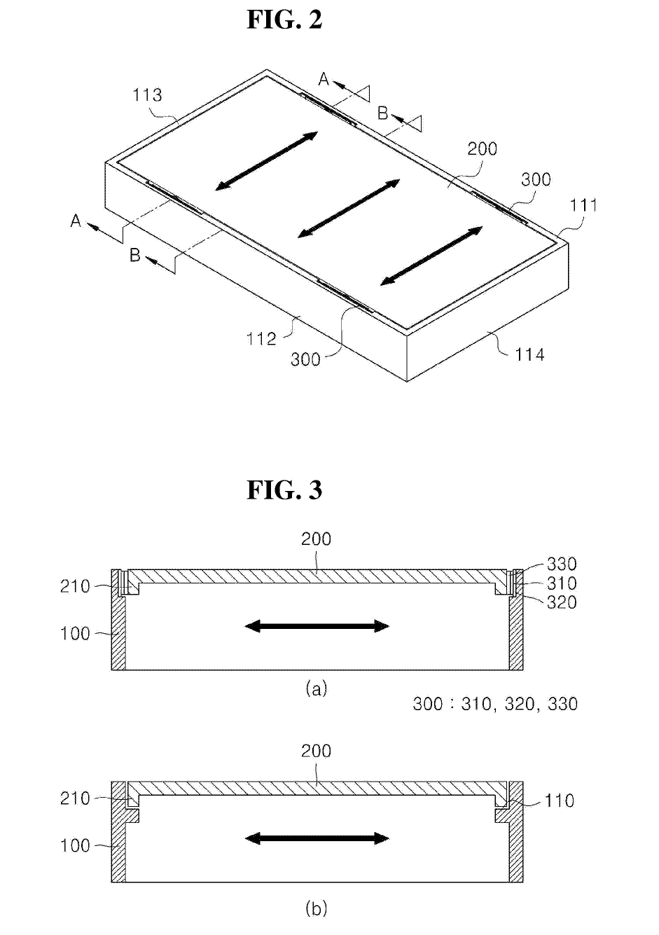

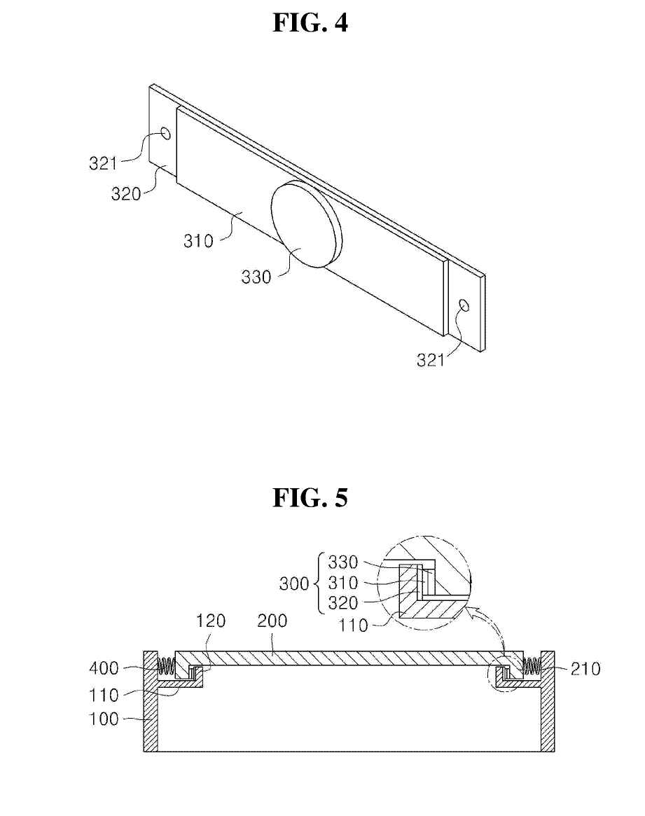

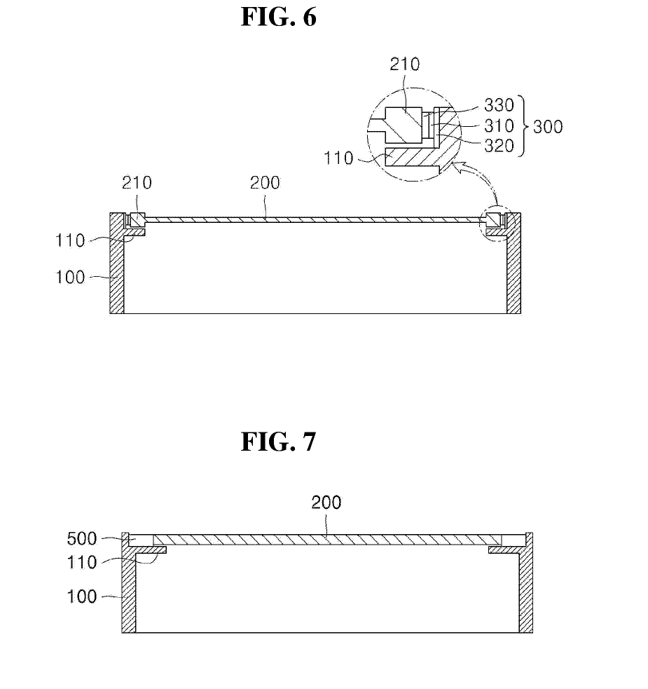

FIG. 1 is an exploded perspective view of a touch screen apparatus in accordance with an exemplary embodiment, FIG. 2 is an assembled perspective view, and FIG. 3 is an assembled cross-sectional view. In addition, FIG. 4 is a perspective view of a piezoelectric vibration member used in a touch screen apparatus. Here, (a) of FIG. 3 and (b) of FIG. 3 are cross-sectional views respectively taken along lines A-A′ and B-B′ of FIG. 2.

Referring to FIGS. 1 to 3, a touch screen apparatus in accordance with an exemplary embodiment may include: a frame 100 providing a predetermined space, a touch screen panel 200 provided at an upper side in the frame 100; and a piezoelectric vibration member 300 provided in a predetermined region on an inner side surface of the frame 100, contacting the touch screen panel 200 to thereby provide vibration force through the touch screen panel 200. Here, the piezoelectric vibration member 300, one surface of which is fixed to a predetermined region on the inner side surface of the frame 100 and the other surface of which faces the one surface and contacts a side surface of the touch screen panel 200, provides vibration to the touch screen panel 200 in the horizontal direction, that is, in a planar direction of the touch screen panel 200. That is, the piezoelectric vibration member 300 is provided between the inner side surface of the frame 100 and the outer surface of the touch screen panel 200 and generates vibration in the planar direction of the touch screen panel 200. Such a touch screen apparatus may be applied to a mobile electronic apparatus, such as a tablet or a smartphone, and may also be mounted inside a vehicle. For example, the touch screen apparatus may be mounted on a center fascia according to an interior design of a vehicle, and in an exemplary embodiment, the case in which the touch screen apparatus is applied to a vehicle is described.

The frame 100 has a predetermined space therein, and the touch screen panel 200 is provided in an inner upper portion of the frame 100. The frame 100 may be provided in a shape having opened upper and lower portions and closed side surfaces. In addition, the frame 100 may be provided in a shape having an opened upper portion and closed lower and side surfaces. The frame 100 may be mounted on a predetermined region in the center fascia of a vehicle. That is, the frame 100 may have a shape in which side surfaces thereof contact the center fascia of the vehicle, predetermined components for operating an audio, a navigation, or the like are accommodated or mounted therein, and the touch screen panel 200 is provided on an upper portion thereof. Of course, when applied to an electronic apparatus such as a tablet, a smartphone, or the like, the frame 100 may be provided in the shape of the electronic apparatus, and predetermined components may be accommodated inside the frame 100. The frame 100 has an approximately rectangular frame shape and may be variously modified according to an applied product. For example, as illustrated in FIG. 1, the frame 100 may include a first side surface 111, a second side surface 112 which face each other in the up-down direction, and third and fourth surfaces 113 and 114 which are respectively provided between two edges of the first and second side surfaces 111 and 112 to face each other. Here, the length of the second side surface 112 may be smaller than that of the first side surface 111, and accordingly, the third and fourth surfaces 113 and 114 may form an acute angle with the first side surface 111 and may form a dull angle with the second side surface 112. Of course, such a shape may be variously modified according to the shape a product in which the frame 100 is applied. For example, the shape of the frame 100 may be variously modified according to a structure of a center fascia in a vehicle or a shape to be mounted on the center fascia. Meanwhile, at least one piezoelectric vibration member 300 may be fixed to at least one region, for example, to the insides of the first and second side surfaces 111 and 112, and the region to which the piezoelectric vibration member 300 is fixed may be formed in a thickness smaller than those of the remaining regions. That is, the piezoelectric vibration member 300 may be housed in a fixing groove provided in a predetermined region of the first and second side surfaces 111 and 112. In addition, in a predetermined region on the inner side surface of the frame 100, a stepped end portion 110 inwardly extending from a side surface of the frame 100 may be provided. That is, the stepped end portion 110 may be formed to protrude by a predetermined width from the inner side surface of the frame 100 toward the inside of the frame 100. A position at which the stepped end portion 110 is formed may be determined according to the thickness of the touch screen panel 200. That is, when the touch screen panel 200 is positioned on the stepped end portion 110 to be spaced apart a predetermined distance from the stepped end portion 110, the upper surface of the touch screen panel 200 may be coplanar with that of the frame 100. The stepped end portion 110 may be formed at, for example, a position with a height of approximately 1/10 to approximately ⅕ of the height of the frame 100. The stepped end portion 110 may be provided to support an edge of the touch screen panel 200 through an adhesive (not shown). That is, the touch screen panel 200 may be supported by the stepped end portion 110 by being attached through an adhesive or the like without directly contacting the stepped end portion 110. The adhesive may be provided in at least some portions between the stepped end portion 110 and the touch screen panel 200. That is, the adhesive may be provided in all regions between the stepped end portion 110 and the touch screen panel 200 or may also be provided in at least two regions. Of course, the stepped end portion 110 and the touch screen panel 200 may be spaced apart a predetermined distance from each other without an adhesive provided therebetween. That is, the touch screen panel 200 may also be upwardly spaced apart a predetermined distance from the stepped end portion 110. As such, when the stepped end portion 110 and the touch screen panel 200 maintain a predetermined distance, vibration force from the piezoelectric member 300 may be more strongly transmitted. In addition, at least a portion of the stepped end portion 110 in a region in which the piezoelectric vibration member 300 is provided may be removed. For example, when the size of the piezoelectric vibration member 300 is greater than the thickness of the touch screen panel 200, the stepped end portion 110 may be removed from the region in which the piezoelectric vibration member 300 is provided. Furthermore, when the size of the piezoelectric vibration member 300 is equal to or smaller than the thickness of the touch screen panel 200, the stepped end portion 110 may be partially removed. A signal line for driving the piezoelectric vibration member 300 may be connected through the removed region of the stepped end portion 110.

The touch screen panel 200 is provided inside the frame 100 and also allows a user to touch the surface thereof. Here, the touch screen panel 200 may not directly contact the frame 100. That is, the touch screen panel 200 may not directly contact the frame 100 because the touch screen panel 200 is provided to be spaced apart from the frame 100, or an adhesive or the like is provided between the touch screen 200 and the frame 100. The touch screen panel 200 may be provided to have a transparent and fusible material. Accordingly, the touch screen panel 200 is disposed to be in close contact into a display (not shown) such as an LCD displaying an image and thereby allow a user to operate the corresponding electronic apparatus while viewing the image displayed on the display through the touch screen panel 200. That is, the touch screen panel 200 is a portion which receives a pressure from the electronic apparatus and an outer surface receiving a signal input from the outside commonly through a finger of a user or a dedicated pen. In addition, a display, a sensor (not shown) detecting a push of an operation menu for a navigation or an audio which are displayed on the display, a protective film (not shown) covering the sensor, and a controller (not shown) controlling the display such that the operation menu for the navigation or the audio is displayed on the display and operating the navigation or the audio in response to a signal detected by the sensor may be provided inside the frame 100 under the touch screen panel 200. That is, the operation menu for the navigation or the audio is displayed on the display by the controller. When the operation menu displayed on the display is touched, the sensor detects the touch and transmits a signal to the controller, and the controller may control the operation of the navigation or the audio on the basis the signal. Here, when the sensor detects a touch, the controller also drives the piezoelectric vibration member 300 to thereby vibrate the touch screen panel 200, and thus, a user may detect the vibration. Meanwhile, the above-mentioned devices accommodated inside the frame 100 under the touch screen panel 200 are well-known techniques widely used in many fields, and the detailed description thereof will not be provided. Also, the touch screen panel 200 may be provided to have a shape of the inside of the frame 100 and the distance between the frame 100 and the touch screen panel 200 may be the same in all regions. Here, the thickness of the piezoelectric vibration member 300 may be equal to the distance between the frame 100 and the touch screen panel 200. That is, when the piezoelectric vibration member 300 has the thickness equal to the distance between the frame 100 and the touch screen panel 200, the touch screen panel 200 may have an area smaller than the area inside the frame 100 so as to have the same distance from the inner side surface of the frame 100 in all regions. However, the region in which the piezoelectric vibration member 300 is provided between the frame 100 and the touch screen panel 200 may have a distance from the frame 100 greater than those of other regions. That is, when the piezoelectric vibration member 300 has the thickness greater than the distance between the frame 100 and the touch screen panel 200, a predetermined groove is formed in the region contacting the piezoelectric vibration member 300 of the touch screen panel 200 and the piezoelectric vibration member 300 may be accommodated in the groove. Furthermore, the touch screen panel 200 may have edges thicker than other regions thereof. That is, the touch screen panel 200 is provided with a protrusion part 210 having a downwardly extending region corresponding to the stepped end portion 110 of the frame 100. The protrusion part 210 may downwardly protrude from edges of the touch screen panel 200 and thereby face the stepped end portion 110, and the width of the protrusion part 210 may be equal to the width of the stepped end portion 110. Of course, the width of the protrusion part 210 may be greater than or smaller than that of the stepped end portion 110, and when the width of the protrusion part 210 is greater than that of the stepped end portion 110, a touch region is reduced. Therefore, the width of the protrusion part 210 is favorably smaller than or equal to the width of the stepped end portion 110. The protrusion part 210 and the stepped end portion 110 may be upwardly spaced apart from each other, and an adhesive such as a double-sided tape is provided in at least some regions between the protrusion part 210 and the stepped end portion 110, and thus, the touch screen panel 200 may be fixed on the frame 100 through the adhesive.

The piezoelectric vibration member 300 is fixed to the inner side surface of the frame 100 and to the outside surface of the touch screen panel 200. The piezoelectric vibration member 300 may be provided in plurality, for example, two piezoelectric vibration members 300 may be provided to be spaced apart from each other on the first side surface 111 of the frame 100, and two piezoelectric vibration members 300 may be provided to be spaced apart from each other on the second side surface 112 of the frame 100, the second side surface 112 facing the first side surface 111. As illustrated in FIG. 4, the piezoelectric vibration member 300 may include a piezoelectric element 310, a vibration plate 320, and a damper 330. That is, the vibration plate 320, the piezoelectric element 310, and the damper 330 are provided from the inner side surface of the frame 100 such that the vibration plate 320 may be brought into contact with and fixed to the inner side surface of the frame 100 and may contact the touch screen panel 200 through the damper 330. Here, the vibration plate 320 may be fastened to the inner side surface of the frame 100 by using a screw or may be attached by using an adhesive. The vibration plate 320 may be firmly fixed by having a fastening hole 321 formed therein and being fastened by using a screw even under a shock due to a strong vibration or collision or under a thermal shock due to a high temperature. Also, the vibration plate 320 may be coupled to the inner side surface of the frame 100 by means of a coupling pin. For example, a groove is formed in a predetermined region of the frame 100, a protrusion part is provided in a predetermined region of the vibration plate 320 corresponding to the groove. Accordingly, the protrusion part of the vibration plate 320 is inserted in the groove of the frame 100 to be thereby fastened to the groove. Here, a region having a greater width is formed in an end of the protrusion of the vibration plate 320 and may thereby prevent the vibration plate 320 from being released after the protrusion part is inserted in the groove. Meanwhile, the vibration plate 320 is provided on the side of the touch screen panel 200, and the damper 330 may be provided between the touch screen panel 200 and the vibration plate 320. In this case, the piezoelectric element 310 may be attached to the inner side surface of the frame 100 by using an adhesive or may be fixed such that at least one region thereof is fastened by a screw. The piezoelectric vibration member 300 may apply vibration in the horizontal direction from the inner side surface of the frame 100, that is, in the direction of the plane of the touch screen panel 200 and may thereby provide great vibration force. That is, when the piezoelectric vibration member 300 perpendicularly contacts the surface of the touch screen panel 200, for example, contacts the stepped end portion 110, vibration force is provided in the direction perpendicular to the surface of the touch screen panel 200. In this case, since the vibration force is locally applied, the farther from the piezoelectric vibration member 300, the smaller the vibration force is transmitted, and the smallest vibration force is transmitted to the central portion of the touch screen panel 200. However, in an exemplary embodiment, since the piezoelectric vibration member 300 applies vibration force in the horizontal direction of the plane of the touch screen panel 200, all regions of the touch screen panel 200 and particularly, the region even the farthest distance from the piezoelectric vibration member 300 may receive strong vibration force.

The piezoelectric vibration member 300 includes a piezoelectric element 310 and a vibration plate 320, and thereby generates vibration due to an inverse piezoelectric effect in which bending stress is generated due to an applied voltage. That is, the piezoelectric element 310 performs extension and contraction motions in the direction of the plane of the touch screen panel 200 according to an applied voltage, and the vibration plate 320 converts the motions into a bending deformation to thereby generate vibration. The piezoelectric element 310 includes a substrate and a piezoelectric layer on which the substrate is formed on at least one surface thereof. For example, the piezoelectric element 310 may be formed in a bimorph type in which piezoelectric layers are formed on both surfaces of the substrate and may also be formed in a unimorph type in which a piezoelectric layer is formed on one surface of the substrate. The piezoelectric layer may be formed such that at least one layer is laminated, and a plurality of piezoelectric layers may favorably be laminated. Furthermore, electrodes may respectively be formed in upper and lower portions of the piezoelectric layer. Also, in order to increase a displacement and vibration force and to enable a low-voltage drive, a plurality of piezoelectric layers may be laminated and also formed in a unimorph type. Here, the piezoelectric layer may be formed by using piezoelectric materials, such as Pb, Zr, or Ti (PZT), Na, K and Nb (NKN), Bi, Na, and Ti (BNT) based materials. In addition, the substrate may be formed by using a material, which has a property of being capable of generating vibration while maintaining a structure in which piezoelectric layers are laminated, such as metal, plastic, or the like. Meanwhile, an electrode terminal may be provided on at least one end portion of the substrate. The piezoelectric element 310 is attached to one surface of the vibration plate 320 by using an adhesive or the like. Here, the piezoelectric element 310 may be attached to the central portion of the vibration plate 320 such that both sides of the vibration plate 320 remain in the same lengths. Furthermore, the piezoelectric element 310 may be attached to one surface of the vibration plate 320, may also be attached to the other surface of the vibration plate 320, and may also be attached to both upper and lower surfaces of the vibration plate 320. That is, in the description of the current embodiment, the piezoelectric element 310 is attached to one surface of the vibration plate 320, but the piezoelectric element 310 may also be attached to the other surface of the vibration plate 320, and may also be attached to one and the other surfaces of the vibration plate 320. Here, the piezoelectric element 310 and the vibration plate 320 may be fixed through various methods other than attachment. For example, the vibration plate 320 and the piezoelectric element 310 are stuck by using an adhesive, and the side surfaces thereof are attached by using an attaching agent, whereby the vibration plate 320 and the piezoelectric element 310 may also be fixed. Meanwhile, the vibration plate 320 may be manufactured by using metal, plastic, or the like, and a dual structure in which different kinds of materials are laminated may be used. For example, the vibration plate 320 may be formed of an alloy, such as stainless or an alloy of iron and a nickel (63.5Fe, 36Ni, and 0.5Mn).

Furthermore, the vibration plate 320 may have an elastic modulus of approximately 1.97×10⁴ to 0.72×10⁶ kg/cm².

The piezoelectric element 310 and the vibration plate 320 may be manufactured in an approximately rectangular plate shape. That is, the piezoelectric element 310 and the vibration plate 320 may respectively be manufactured in shapes having predetermined lengths, widths and thicknesses and having one and the other surfaces facing each other. For example, the vibration plate 320 may be provided in a length of approximately 10 mm to approximately 80 mm and a thickness of approximately 0.05 mm to approximately 0.5 mm. In addition, the piezoelectric element 310 may be manufactured in a length shorter than the vibration plate 320. In the piezoelectric vibration member 300, one surface of the vibration plate 320 is attached to one surface of the piezoelectric element 310, and the other surface of the vibration plate 320 is coupled to the inner side surface of the frame 100. In addition, when the piezoelectric element 310 is attached to the other surface of the vibration plate 320, the piezoelectric element 310 and the frame 100 may be coupled. Also, the vibration plate 320 may have a curvedly formed predetermined region except for the region to which the piezoelectric element 310 is attached. That is, the vibration plate 320 at the outer side of the region to which the piezoelectric element 310 is attached may have a predetermined curvature, for example, may have a shape which is downwardly bent and then upwardly bent again. In addition, a flat region may be formed again outside the curved region, and the flat region may contact the inner side surface of the frame 100. In other words, the vibration plate 320 may be manufactured such that a first region contacting the piezoelectric element 310 and a second region contacting the frame 100 are provided in plate shapes, and a curved third region is provided between the first and second regions. Of course, the vibration plate 320 may be manufacture such that all regions thereof have the same shape, that is, manufactured in a plate shape. That is, the vibration plate 320 may be manufactured in a flat plate shape, and edges thereof may contact the frame 100. The damper 330 is provided between the piezoelectric vibration member 300 and the touch screen panel 200. The damper 330 may be fixed to the piezoelectric vibration member 300 and may not be attached to the touch screen panel 200. However, in order to stably support the touch screen panel 200, the damper 330 may also be attached to the touch screen panel 200. In order to attach the damper 330 to the piezoelectric vibration member 300 and the touch screen panel 200, an adhesive such as a double-sided tape may be used, and at this time, the adhesive such as a double-sided tape may be provided in a thickness of approximately 0.05 mm to approximately 1.0 mm. Of course, the damper 330 may be formed of an adhesive material such as rubber or silicone and may thereby be self-attached to the piezoelectric vibration member 300 and the touch screen panel 200. The damper 330 may be provided by using polyurethane, polycarbonate, rubber, silicone, PORON, or the like. When a product is dropped or shocked, damage to the product may be prevented by providing the damper 330 as described above. In addition, vibration force may be transmitted without loss by concentrating the vibration of the piezoelectric vibration member 300.

Meanwhile, the piezoelectric vibration member 300 may further have a waterproof layer (not shown) formed in at least a portion thereof. The waterproof layer may be coated by using a waterproof material, such as parylene. Parylene may be formed on upper and side surfaces of a piezoelectric plate 310 and on upper and side surfaces of the vibration plate 320 exposed by the piezoelectric plate 310 while the piezoelectric plate 310 is attached on the vibration plate 320. That is, parylene may be formed on the upper and side surfaces of the piezoelectric plate 310 and the vibration plate 320. In addition, parylene may be formed on upper and side surfaces of the piezoelectric plate 310 and on upper, side, and lower surfaces of the vibration plate 320 while the piezoelectric plate 310 is attached on the vibration plate 320. That is, parylene may be formed on the upper, side, and lower surfaces of the piezoelectric plate 310 and the vibration plate 320. Since parylene is formed on at least one surface of the piezoelectric plate 310 and the vibration plate 320, moisture penetration into the piezoelectric vibration member 300 and oxidation of piezoelectric vibration member 300 may be prevented. Furthermore, a response speed may also be improved by increasing the hardness of the vibration plate 320. In addition, a resonant frequency may be adjusted according to the coated thickness of parylene. Of course, parylene may be applied only on the piezoelectric plate 310, may be applied on upper, side, and lower surfaces of the piezoelectric plate 310, and may be applied on a power line such as an FPCB for supplying power to the piezoelectric plate 310 by being connected to the piezoelectric plate 310. Since parylene is formed on the piezoelectric plate 310, moisture penetration into the piezoelectric plate 310 may be prevented, and the oxidation of the piezoelectric plate 310 may be prevented. Furthermore, a resonant frequency may be adjusted by adjusting the forming thickness of parylene. Such parylene may be applied with a different thickness according to a material and a characteristic of the piezoelectric plate 310 or the vibration plate 320 and may be formed in a thickness smaller than the thickness of the piezoelectric plate 310 or the vibration plate 320, for example, formed in a thickness of approximately 0.1 μm to approximately 10 μm. In order to coat with parylene as described above, for example, parylene is firstly heated to be vaporized into a dimmer state in a vaporizer, is then secondly heated to be thermally decomposed into a monomer state, is then cooled to be converted into a polymer state, and may thus be applied on at least one surface of the piezoelectric vibration member 300. Meanwhile, the waterproof layer such as parylene may also be formed on the damper 330 of the piezoelectric vibration member 300.

In addition, although not shown, the piezoelectric vibration member 300 may also be accommodated in a predetermined case. For example, a C-shaped case is provided, the piezoelectric element 310 is then accommodated inside the case, and then, the vibration plate 320 may be fixed to an opened region of the case. That is, the piezoelectric element 310 may be accommodated in the C-shaped case, and the vibration plate 320 may cover the opened region of the case. Here, in the vibration plate 320, the damper 330 may be provided on the other surface on which the piezoelectric element 310 is not attached. The case may be formed of a metallic material such as aluminum or plastic, and an FPCB may be attached on one surface. That is, the FPCB may be attached on a surface facing the one surface covered by the vibration plate 320. As such, since the case is provided so as to accommodate at least a portion of the piezoelectric vibration plate 300, the case may protect the piezoelectric vibration plate 300 and an FPCB terminal.

As described above, in the touch screen apparatus according to an exemplary embodiment, the piezoelectric vibration member 300 is provided on the inner side surface of the frame 100 so that the side surface of the touch screen panel 200 contacts the piezoelectric vibration member 300. Accordingly, the piezoelectric vibration member 300 vibrates in the horizontal direction with respect to the plane of the touch screen panel 200, and vibration force is thereby provided in the horizontal direction of the touch screen panel 200. Consequently, in comparison with vibration in the direction perpendicular to the touch screen panel in related arts, the vibration force may be increased, and uniform vibration force may be received by all regions in the touch screen panel.

Furthermore, since the piezoelectric vibration member 300 is provided on the inner side surface of the frame 100, the space utilization is less limited than that in related arts. In addition, since vibration is generated in the horizontal direction on the side surface of the touch screen panel 200, an unpleasant touch feeling is less generated. Furthermore, edges of the touch screen panel 200 are formed in a great thickness and the piezoelectric vibration member 300 may thereby contact the entire side surface of the touch screen panel 200. Thus, vibration force may be increased.

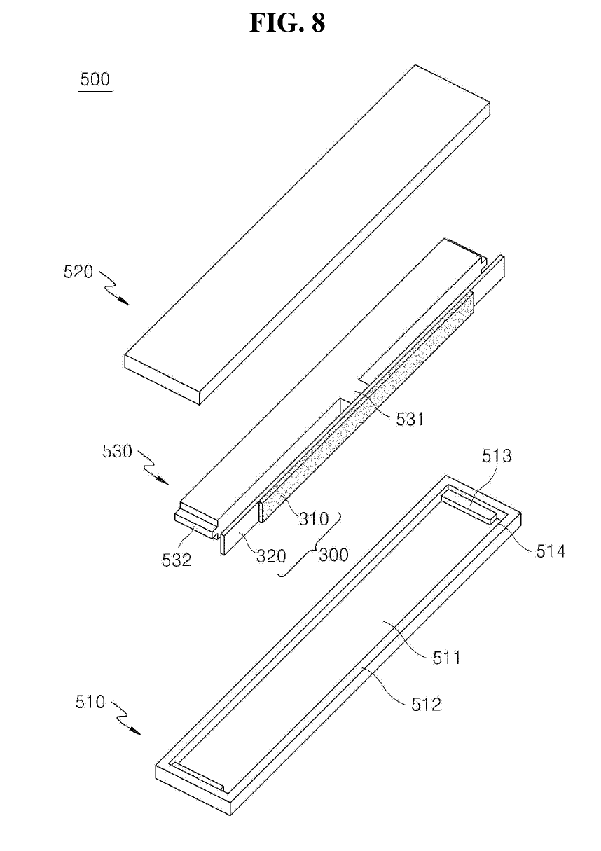

FIGS. 5 to 7 are cross-sectional views of touch screen apparatuses in accordance with various exemplary embodiments.

Referring to FIG. 5, in a touch screen apparatus according to a second exemplary embodiment, an extension part 120 is provided to upwardly extend from the inner side of a stepped end portion 110, and a piezoelectric vibration member 300 may be fixed on the inner side surface of the extension part 120. The extension part 120 may be provided in a height smaller than the thickness of the edges of the touch screen panel 200 and a predetermined distance may be maintained between the upper surface of the extension part 120 and the touch screen panel 200. Here, the edges of the touch screen panel 200 may be provided in a region between the frame 100 and the extension part 120, and a cushion member such as a spring 400 may be provided between the frame 100 and the touch screen panel 200. That is, the cushion member such as the spring 400 may be provided between the frame 100 and the touch screen panel 200, and the piezoelectric vibration member 300 may be provided between the touch screen panel 200 and the extension part 120. The cushion member such as the spring 400 may be extended between the frame 100 and the touch screen panel 200 to thereby fix the frame 100 and the touch screen panel 200. Also, the touch screen panel 200 and the stepped end portion 110 may be spaced apart a predetermined distance from each other, and an adhesive (not shown) may be provided in at least some regions between the touch screen panel 200 and the stepped end portion 110. In the touch screen apparatus according to the second exemplary embodiment, the piezoelectric vibration member 300 provides vibration force in the horizontal direction of the touch screen panel 200, and accordingly, the touch screen panel 200 vibrates in a planar direction thereof.

Referring to FIG. 6, in a touch screen apparatus according to a third exemplary embodiment, a predetermined width of edges of a touch screen panel 200 is formed greater than those of other regions in upward and downward direction. That is, the edges are formed to have thickness greater than those of other regions in upward and downward direction. Accordingly, a touch region of the touch screen panel 200 is formed lower than the edges of the touch screen panel 200. Here, the width of the edges may be formed equal to that of a stepped end portion of a frame 100, and an upper surface of the edges may be coplanar with an upper surface of the frame 100.

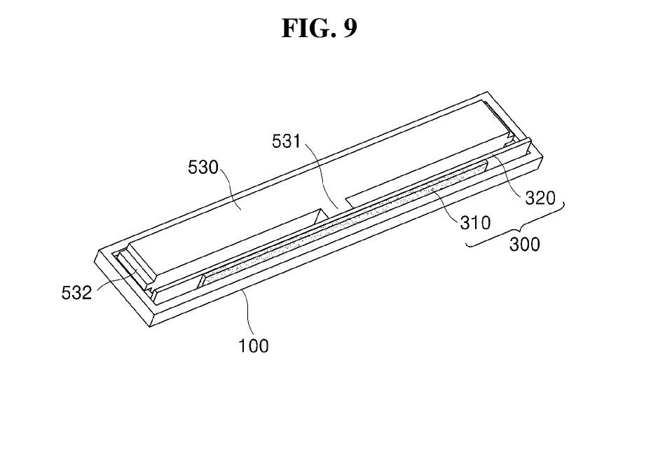

Referring to FIG. 7, a touch screen apparatus according to a third exemplary embodiment includes a piezoelectric vibration module 500. That is, a piezoelectric vibration module 500 is provided between a frame 100 and a touch screen panel 200. As illustrated in FIG. 8, the piezoelectric vibration module 500 may include: lower and upper cases 510 and 520 which are coupled so as to provide a predetermined space therein; a piezoelectric vibration member 300 provided in the inner space between the lower and upper cases 510 and 520; and a weight member 530 provided in the inner space between the lower and upper cases 510 and 520 and coupled to a portion of the piezoelectric vibration member 300 to thereby amplify the vibration of the piezoelectric vibration member 300. The configuration of the piezoelectric vibration module 500 will be described in more detail using FIGS. 8 and 9. Furthermore, the touch screen panel 200 may be provided such that all regions thereof have the same thicknesses. That is, in the first to third exemplary embodiments, edges are provided to have thicknesses greater than other regions, but in the fourth exemplary embodiment, the touch screen panel 200 may be provided to have the same thickness in all regions thereof. Of course, also in the fourth exemplary embodiment, the edges of the touch screen panel 200 may also have thickness greater than other regions thereof.

Using FIGS. 8 and 9, a piezoelectric vibration module 500 will be described as follows. A piezoelectric vibration module 500 may include: lower and upper cases 510 and 520; a piezoelectric vibration member 300 provided in an inner space between the lower and upper cases 510 and 520; and a weight member 530 provided in the inner space between the lower and upper cases 510 and 520 and coupled to a portion of the piezoelectric vibration member 300.

The lower case 510 is provided under the piezoelectric vibration module 500, is coupled to the upper case 520 to thereby provide a predetermined space therein, and forms an exterior shape of the piezoelectric vibration module 500. The lower case 510 may be provided in a shape in which, for example, two sides facing each other in the lengthwise direction are long, and two sides facing each other in the width direction perpendicular to the lengthwise direction are short so that an inner space is provided along the shape of the piezoelectric vibration member 300 and the weight member 530. The lower case 510 may include: a planar surface part 511 which is spaced apart a predetermined distance from the piezoelectric vibration member 300 and may thereby cover the lower side of the piezoelectric vibration member 300; and four side surface parts 512 upwardly extending from edges of the planar surface part 511. Meanwhile, a horizontal part 513 which extends toward the outside facing the planar surface part 511 over the side surface parts 512 extending from the edges of the short sides of the planar surface part 511 may be further formed. That is, the planar surface part 511 of the lower case 510 is provided to have a length shorter than the length of the weight member 530, and the horizontal part 513 which extends toward the outside facing the planar surface part 511 over the side surface parts 512 extending from the edges of the short sides of the planar surface part 511 may be further formed in a length equal to or greater than the length of the weight member 530. In addition, a hole 514 in which a vibration plate 320 is inserted is formed in a predetermined region, that is, in an outer side of the planar surface part 511. The hole 514 may be formed in a diameter equal to the thickness of one region of the vibration plate 320 so as to contact one region of the vibrating plate 320.

The upper case 520 is coupled to the lower case 510 to thereby provide a predetermined space therein. The upper case 520 is provided over the weight member 530 and accommodates the weight member 530 therein and at least a portion of the piezoelectric vibration member 300 therein. That is, the weight member 530 may be provided in the upper case 520, and the piezoelectric vibration member 300 may be provided in a space between the lower and upper cases 510 and 520. The upper case 520 may be provided in a shape in which two sides facing each other are long, and two sides facing each other in the perpendicular direction thereto are short so that an inner space is provided along the shape of the piezoelectric vibration member 300 and the weight member 530. That is, the upper case 520 may include a planar surface part and four side surface parts extending from the edges of the planar surface part in the direction toward the lower case 510, and the planar surface part may have two long sides in the lengthwise direction of the weight member 530 and two short sides in the width direction of the weight member 530. In addition, the side surface part of the upper case 520 may also downwardly extend from all regions of the edges of the planar surface part and may also downwardly extend from at least a portion of the edges. That is, the side surface part may partially extend from the edges of the planar surface part. Here, the side surface part of the upper case 520 may be provided so as to surround the side surface part 512 of the lower case 510 from the outer side thereof. That is, the piezoelectric vibration module 500 may be realized such that he piezoelectric vibration member 300 and the weight member 540 are accommodated therein and the side surface part of the upper case 520 and the side surface part 512 of the lower frame 510 are coupled. In addition, the upper case 520 may be manufactured to have the length, height and width of the side surface part greater than those of the weight member 530 so as to accommodate the weight member 530 therein. That is, the upper case 520 may be provided so that the weight member 530 may be spaced apart a predetermined distance from the planar surface part and the side surface part of the upper case 520 in the inner space of the upper space 520.

The piezoelectric vibration member 300 includes a piezoelectric element 310 and the vibration plate 320, the piezoelectric element 310 is attached to one surface of the vibration plate 320, and the other surface of the vibration plate 320 contacts the weight member 530. In addition, the vibration plate 320 is provided in length greater than the piezoelectric element 310, and the edges of the vibration plate 320 is inserted in the hole 514 of the lower case 510. Since the piezoelectric element 310 and the vibration plate 320 of the piezoelectric vibration member 300 is the same as those in an exemplary embodiment, detailed descriptions thereof will not be provided.

The weight member 530 has an approximately hexahedral shape having predetermined length, width, and thickness. Here, two surfaces facing each other in the width direction may be wider than two surfaces facing each other in the thickness direction. In addition, the weight member 530 has a contact part 531 formed in the side of the piezoelectric vibration member 300 and the contact part 531 contacts the piezoelectric vibration member 300. That is, the contact part 531 may be provided in a central portion of one surface in the thickness direction of the weight member 530 facing one surface of the piezoelectric vibration member 300 and may thereby contact the central portion of the piezoelectric vibration member 300. Here, the one surface of the weight member 530 in which the contact part 531 is horizontally provided, the contact part 531 is provided to protrude from the central portion the weight member 530, and the highest portion of the central portion serves as the contact part 531 and may contact the piezoelectric vibration member 300. Here, the contact part 531 and piezoelectric vibration member 300 may be fixed by being attached by using adhesive or the like. Accordingly, the contact part 531 may contact the piezoelectric vibration member 300, and the remaining region of the weight member 530 may be spaced apart from the piezoelectric vibration member 300. The adhesive may be applied in a great thickness according to the types of the adhesive and the characteristics thereof, and according to the applied thickness of the adhesive, the distance between the piezoelectric vibration member 300 and the weight member 530 may be increased, and the thickness of the piezoelectric vibration module 500 may thereby be increased. Thus, the region in which the adhesive is applied, that is, the contact part 531 may have a recess part inwardly recessed according to the applied thickness of the adhesive. Meanwhile, the contact part 531 may not be positioned at the central portion of the weight member 530 and may be moved by approximately 10% or less from the central portion. Accordingly, a vibration frequency and a displacement may be adjusted. While vibrating together with the piezoelectric vibration member 300 due to vibration of the piezoelectric vibration member 300, the weight member 430 coupled to the piezoelectric vibration member 300 as described above applies the weight thereof to the vibration. As such, when the weight member 530 is coupled to the piezoelectric vibration member 300 and the weight of the weight member 530 is loaded, the weight of the vibrating body is consequently increased, and a resonant frequency is decreased while vibration force is reinforced in comparison with the case in which the piezoelectric vibration member 300 vibrates alone. In particular, at a specific frequency of alternating current drive voltage, the vibration force is maximally amplified. In addition, when the weight member 530 is used, since current flowing in the piezoelectric vibration member 300 is small, the amount of power consumption may be greatly reduced. Meanwhile, an extension part 532 is formed at both ends in the lengthwise direction of the weight member 530. The extension part 532 is formed in a smaller thickness than a main body, for example, in a thickness of approximately ½ of the thickness of the main body. The extension part 532 may be provided on the horizontal part 513 of the lower case 510 so as not to contact the horizontal part 513 of the lower case 510.

The characteristics of the frequency and vibrational acceleration in an example and a comparative example are compared in Table 1. Here, the vibrational acceleration is the strength of vibration force received by the touch screen panel when the piezoelectric vibration member contacts a touch screen panel. In the example, the piezoelectric vibration member vibrates in the horizontal direction with respect to the touch screen panel and in the comparative example, and the piezoelectric vibration member vibrates in the vertical direction with respect to the touch screen panel. That is, in the example, the piezoelectric vibration member was provided between the inner side surface of the frame and the outer side surface of the touch screen panel, and in the comparative example, the piezoelectric vibration member was provided on a lower surface of the touch screen panel. In order to compare the characteristics of the example and the comparative example, five positions at the same positions on the touch screen panel were measured. At this time, an input voltage was set to approximately 150 V, a sine wave was applied for approximately 10 seconds, and a frequency was varied from approximately 100 Hz to approximately 300 Hz.

TABLE 1

| | | position | | | | | | |
|---|---|---|---|---|---|---|---|---|
| Type | Characteristic | 1 | 2 | 3 | 4 | 5 | Average | Deviation |
| Comparative | Frequency | 224 | 312 | 206 | 200 | 312 | 251 | 56.561 |
| example | (Hz) | | | | | | | |
| | Vibratinonal | 1.839 | 2.073 | 3.384 | 1.147 | 0.801 | 1.849 | 1.000 |
| | acceleration | | | | | | | |
| | (g) | | | | | | | |
| Example | Frequency | 166 | 172 | 168 | 164 | 170 | 168 | 3.162 |
| | (Hz) | | | | | | | |
| | Vibratinonal | 3.546 | 3.744 | 4.3 | 3.801 | 4.081 | 3.899 | 0.290 |
| | acceleration | | | | | | | |
| | (g) | | | | | | | |

| | | | | | | | |
|---|---|---|---|---|---|---|---|
| Rate of change in Vibrational | 94 | 80 | 27 | 231 | 409 | — | — |
| acceleration (%) | | | | | | | |

As shown in Table 1, it may be found that the vibration acceleration according to the example is increased in comparison with the comparative example. That is, in comparison with the comparative example, the vibration acceleration in the example is increased by approximately 27% to approximately 409%. In addition, it may be found that the deviation of the vibration acceleration, that is, the error for each region in the example is smaller than that in the comparative example. Accordingly, in the example, vibration force greater than that in the comparative example may be received and a substantially uniform vibration force may be received in all regions of the touch screen panel.

In accordance with an exemplary embodiment, a touch screen apparatus is provided with a piezoelectric vibration member on an inner side surface of a frame and the piezoelectric vibration member is provided so as to be in contact with a side surface of a touch screen panel. The piezoelectric vibration member vibrates in the horizontal direction with respect to a planar surface of the touch screen panel, and accordingly, vibration force is transferred in the horizontal direction of the touch screen panel. Accordingly, in comparison with vibration in the vertical direction in related arts, vibration force may be increased, and uniform vibration force may be received by all regions in the touch screen panel.

Furthermore, since the piezoelectric vibration member is provided on an inner side surface of the frame, the space utilization is less limited than that in related arts. In addition, since vibration is generated in the horizontal direction on a side surface of the touch screen panel, unpleasant haptic sense is less generated, and since edges of the touch screen panel is formed in a great thickness and thereby, piezoelectric vibration member may contact the entire side surface of the touch screen panel, and the vibration force may be increased.

The present invention may, however, be embodied in different forms and should not be construed as limited to the embodiments set forth herein. Rather, the embodiments are provided so that this disclosure will be thorough and complete, and will fully convey the scope of the present invention to those skilled in the art. Further, the present invention is only to be defined by the scopes of the claims.

1. A touch screen apparatus comprising:
a frame;
a touch screen panel provided inside the frame; and
a piezoelectric vibration member provided between the frame and the touch screen panel, wherein
the piezoelectric vibration member vibrates in a horizontal direction of the touch screen.

2. The touch screen apparatus of claim 1, wherein
the frame has a shape which has at least an opened upper portion and closed side surfaces, wherein
a stepped end portion is formed on an inner side surface the frame.

3. The touch screen apparatus of claim 2, wherein the frame further comprises a groove formed to accommodate the piezoelectric vibration member in an inner side surface thereof above the stepped end portion.

4. The touch screen apparatus of claim 2, wherein
the touch screen panel is provided to have edges thicker than other regions thereof, wherein
the edges are spaced a predetermined distance from the stepped end portion.

5. The touch screen apparatus of claim 4, further comprising an adhesive provided in at least some regions between the stepped end portion and a lower side of the edges of the touch screen panel.

6. The touch screen apparatus of claim 2, further comprising an extension part upwardly extending from the outer side of the stepped end portion, wherein
the piezoelectric vibration member is provided on a side surface of the extension part.

7. The touch screen apparatus of claim 1, further comprising a cushion member including a spring provided between the frame and the touch screen panel.

8. The touch screen apparatus of claim 1, wherein the piezoelectric vibration member comprises:
a vibration plate having at least one region in which a hole is formed; a piezoelectric element, and
a damper, wherein
the vibration plate is fixed to the frame, and the damper is brought into contact with the touch screen panel.

9. The touch screen apparatus of claim 8, further comprising a waterproof layer formed on at least a portion of the piezoelectric vibration member.

10. The touch screen apparatus of claim 8, wherein the vibration plate is fixed to the frame by at least one of a screw, an adhesive, or coupling pin.

11. The touch screen apparatus of claim 1, further comprising a case accommodating the piezoelectric vibration member.

12. The touch screen apparatus of claim 11, further comprising an FPCB provided on one surface of the case.

13. The touch screen apparatus of claim 11, further comprising a weight member brought into contact with the piezoelectric vibration member inside the case.
